(19) United States
(12) Patent Application Publication
(10) Pub. No.: US 2012/0145214 A1
(43) Pub. Date: Jun. 14, 2012

(54) THERMOELECTRIC CONVERSION MATERIAL, AND THERMOELECTRIC CONVERSION MODULE USING SAME

(75) Inventors: Yuichi Hiroyama, Tsukuba-shi (JP); Hiroshi Kishida, Tsukuba-shi (JP)

(73) Assignee: SUMITOMO CHEMICAL COMPANY, LIMITED, Chuo-ku, Tokyo (JP)

(21) Appl. No.: 13/387,021

(22) PCT Filed: Jul. 16, 2010
(86) PCT No.: PCT/JP2010/062093

§ 371 Date: Mar. 1, 2012

(30) Foreign Application Priority Data
Jul. 31, 2009 (JP) 2009-178997

(51) Int. Cl. H01L 35/28; H01L 35/22; H01L 35/18; H01L 35/14

(52) U.S. Cl. 136/224; 136/236.1; 136/238

(57) ABSTRACT

A thermoelectric conversion material contains a mixed oxide containing Zn, Ga, and In. The thermoelectric conversion material is one in which the mixed oxide further contains Al. The thermoelectric conversion material is one in which the relative density of the mixed oxide is not less than 80%. The thermoelectric conversion material is one in which at least a part of a surface of the mixed oxide is coated with a film. A thermoelectric conversion module is provided with a plurality of n-type thermoelectric conversion materials, a plurality of p-type thermoelectric conversion materials, and a plurality of electrodes electrically serially connecting the p-type thermoelectric conversion materials with the n-type thermoelectric conversion materials in an alternate arrangement, and at least one material of the plurality of n-type thermoelectric conversion materials is the aforementioned thermoelectric conversion material.

### TECHNICAL FIELD

The present invention relates to a thermoelectric conversion material, and a thermoelectric conversion module using the same.

### BACKGROUND ART

The thermoelectric power generation is electric power generation generated by converting thermal energy into electric energy with the use of a phenomenon of voltage generation (thermoelectromotive force) on a occasion that a temperature difference is given to thermoelectric conversion materials, i.e., a phenomenon by the Seebeck effect. Since can be used as thermal energy a variety of exhaust heat, such as geothermal heat and heat generated from incinerators, the thermoelectric power generation is expected as environment conservation type power generation that can be put into practical use.

An efficiency of conversion from thermal energy to electric energy, of a thermoelectric conversion material (which will be sometimes referred to as “energy conversion efficiency”) is dependent upon the value of performance index (Z) of the thermoelectric conversion material. The value of performance index (Z) is a value determined by the formula below, using the value of Seebeck coefficient (α), the value of electrical conductivity (σ), and the value of thermal conductivity (κ) of the thermoelectric conversion material. The larger the value of performance index (Z) of the thermoelectric conversion material, the higher the energy conversion efficiency of the thermoelectric conversion material. Furthermore, α²×σ in the below formula is called power factor and the value of this power factor is also used as an index to indicate the thermoelectric conversion characteristic.

Z=α²×σ/κ

The thermoelectric conversion materials include p-type thermoelectric conversion materials with positive values of the Seebeck coefficient, and n-type thermoelectric conversion materials with negative values of the Seebeck coefficient. The thermoelectric power generation is usually implemented using a thermoelectric conversion module provided with a plurality of p-type thermoelectric conversion materials, a plurality of n-type thermoelectric conversion materials, and a plurality of electrodes electrically serially connecting these materials in an alternate arrangement.

These thermoelectric conversion materials are generally classified, particularly, into metal materials and oxide materials. The oxide materials are more suitable for use in a high-temperature atmosphere. Furthermore, examples of the metal materials include silicide-based materials such as β-FeSi₂, and examples of the oxide materials include zinc oxide-based materials.

A zinc oxide-based thermoelectric conversion material is a thermoelectric conversion material in which a part of Zn in ZnO is substituted with Al, which is disclosed in Patent Literature 1. Non Patent Literature 1 discloses the thermoelectric conversion material in which a part of Zn in ZnO is co-substituted with Al and Ga.

### CITATION LIST

### Patent Literature

Patent Literature 1: JP H08-186293A

### Non Patent Literature

Non Patent Literature 1: (Kiyoshi Yamamoto et al., “Proceedings at 5th Annual Meeting of The Thermoelectrics Society of Japan (TSJ2008)” p 18 (2008))

### SUMMARY OF INVENTION

### Technical Problem

However, the values of performance index are still insufficient with the thermoelectric conversion material in which a part of Zn in ZnO is substituted with Al and with the thermoelectric conversion material in which a part of Zn in ZnO is co-substituted with Al and Ga. As described in Non Patent Literature 1, when a part of Zn in ZnO is substituted with Ga or In, the resulting thermoelectric conversion materials have small values of electrical conductivity and thus an increase is not expected in the value of performance index of the thermoelectric conversion materials. Therefore, the present invention provides a thermoelectric conversion material with an extremely large value of performance index.

### Solution to Problem

The present invention provides the thermoelectric conversion elements and the thermoelectric conversion module described below.

<1> A thermoelectric conversion material comprising a mixed oxide containing Zn, Ga, and In.

<2> The thermoelectric conversion material described in <1> wherein the ratio of a molar amount of Ga to a total molar amount of Zn, Ga, and In is not less than 0.001 and not more than 0.1.

<3> The thermoelectric conversion material described in <1> or <2> wherein the ratio of a molar amount of In to a total molar amount of Zn, Ga, and In is not less than 0.001 and not more than 0.3.

<4> The thermoelectric conversion material described in any one of <1> to <3> wherein the relative density of the mixed oxide is not less than 80%.

<5> The thermoelectric conversion material described in <1> wherein the mixed oxide further contains Al.

<6> The thermoelectric conversion material described in <5> wherein the ratio of a molar amount of Al to a total molar amount of Zn, Ga, Al, and In is not less than 0.001 and not more than 0.1.

<7> The thermoelectric conversion material described in <5> or <6> wherein the ratio of a molar amount of Ga to a total molar amount of Zn, Ga, Al, and In is not less than 0.001 and not more than 0.1.

<8> The thermoelectric conversion material described in any one of <5> to <7> wherein the ratio of a molar amount of In to a total molar amount of Zn, Ga, Al, and In is not less than 0.001 and not more than 0.3.

<9> The thermoelectric conversion material described in any one of <5> to <8> wherein the relative density of the mixed oxide is not less than 80%.

<10> The thermoelectric conversion material described in any one of <1> to <9> wherein at least a part of a surface of the mixed oxide is coated with a film.

<11> A thermoelectric conversion module comprising: a plurality of n-type thermoelectric conversion materials; a plurality of p-type thermoelectric conversion materials; and a plurality of electrodes electrically serially connecting the plurality of p-type thermoelectric conversion materials with the plurality of n-type thermoelectric conversion materials in an alternate arrangement, wherein at least one material of the plurality of n-type thermoelectric conversion materials is the thermoelectric conversion material as described in any one of <1> to <10>.

### Effects of Invention

The present invention allows us to obtain the thermoelectric conversion material providing an extremely large value of performance index. When this thermoelectric conversion material is applied to the n-type thermoelectric conversion materials in the thermoelectric conversion module, it is feasible to implement efficient thermoelectric power generation, and therefore the present invention is extremely useful industrially.

### BRIEF DESCRIPTION OF DRAWINGS

FIG. 1 is a cross-sectional view of an example of the thermoelectric conversion module using thermoelectric conversion materials according to an embodiment of the present invention.

FIG. 2 is a cross-sectional view of another example of the thermoelectric conversion module using thermoelectric conversion materials according to an embodiment of the present invention.

### DESCRIPTION OF EMBODIMENTS

<Thermoelectric Conversion Material>

The thermoelectric conversion material of the present invention comprises the mixed oxide containing Zn, Ga, and In. The thermoelectric conversion material of the present invention has an extremely small value of thermal conductivity (κ), whereby it can provide an extremely large value of performance index (Z=α²×σ/κ). The mixed oxide in the thermoelectric conversion material of the present invention is preferably a mixed oxide in which a part of Zn in ZnO is substituted with the two elements of Ga and In.

In terms of further increasing the value of electrical conductivity (σ) of the thermoelectric conversion material, the ratio of the molar amount of Ga to the total molar amount of Zn, Ga, and In in the foregoing mixed oxide containing Zn, Ga, and In is preferably not less than 0.001 and not more than 0.1 and more preferably not less than 0.002 and not more than 0.02.

In terms of further decreasing the value of thermal conductivity (κ) of the thermoelectric conversion material, the ratio of the molar amount of In to the total molar amount of Zn, Ga, and In in the foregoing mixed oxide containing Zn, Ga, and In is preferably not less than 0.001 and not more than 0.3 and more preferably not less than 0.01 and not more than 0.2.

In the thermoelectric conversion material of the present invention, the mixed oxide preferably further contains Al. Namely, the mixed oxide preferably contains Zn, Ga, Al, and In. In this case, the mixed oxide in the thermoelectric conversion material of the present invention is preferably a mixed oxide in which a part of Zn in ZnO is substituted with the three elements of Ga, Al, and In.

In terms of further increasing the value of electrical conductivity (σ) of the thermoelectric conversion material, the ratio of the molar amount of Al to the total molar amount of Zn, Ga, Al, and In in the foregoing mixed oxide containing Zn, Ga, Al, and In is preferably not less than 0.001 and not more than 0.1 and more preferably not less than 0.002 and not more than 0.02.

In terms of further increasing the value of electrical conductivity (σ) of the thermoelectric conversion material, the ratio of the molar amount of Ga to the total molar amount of Zn, Ga, Al, and In in the foregoing mixed oxide containing Zn, Ga, Al, and In is preferably not less than 0.001 and not more than 0.1 and more preferably not less than 0.002 and not more than 0.02.

In terms of further decreasing the value of thermal conductivity (κ) of the thermoelectric conversion material, the ratio of the molar amount of In to the total molar amount of Zn, Ga, Al, and In in the foregoing mixed oxide containing Zn, Ga, Al, and In is preferably not less than 0.001 and not more than 0.3 and more preferably not less than 0.01 and not more than 0.2.

The thermoelectric conversion material of the present invention is used mainly in the form of powder, a sintered body having a stereoscopic shape, or a thin film and, particularly, in the form of a sintered body having a stereoscopic body. When the sintered body having the stereoscopic body is used for the thermoelectric conversion material of the present invention, below-described raw material compounds are sintered to obtain the sintered body in appropriate shape and size in the thermoelectric conversion module and it is used as the thermoelectric conversion material. Specific examples of stereoscopic shapes include platelike shapes, cylindrical shapes, and prismatic shapes such as a rectangular parallelepiped. Generally, the thermoelectric conversion material formed from the sintered body is used after its end faces, namely surfaces opposing to electrodes in the below-described thermoelectric conversion module, are polished.

<Method of Manufacturing Thermoelectric Conversion Material>

The mixed oxide in the thermoelectric conversion material of the present invention can be manufactured by calcining a mixture of raw material compounds. Specifically, it can be manufactured by weighing respective compounds each containing Zn, Ga, Al, or In corresponding to the mixed oxide in the thermoelectric conversion material of the present invention, so as to achieve a prescribed composition, mixing them, and then calcining the resultant mixture. When the compounds respectively containing Zn, Ga, or In are used, the resulting thermoelectric conversion material is one containing the mixed oxide containing Zn, Ga, and In; when the compounds respectively containing Zn, Ga, Al, or In are used, the resulting thermoelectric conversion material is one containing the mixed oxide containing Zn, Ga, Al, and In.

The foregoing compounds containing the respective elements of Zn, Ga, Al, and In are, for example, oxides, or, compounds or metals that decompose and/or oxidize at high temperature to become oxides, such as hydroxides, carbonates, nitrates, halides, sulfates, and salts of organic acids. Examples of applicable compounds containing Zn include zinc oxide (ZnO), zinc hydroxide (Zn(OH)₂) and zinc carbonate (Zn(CO₃)), and zinc oxide (ZnO) is particularly preferable. Examples of applicable compounds containing Al include aluminum oxide (Al₂O₃) and aluminum hydroxide (Al(OH)₃), and aluminum oxide (Al₂O₃) is particularly preferable. Examples of applicable compounds containing Ga include gallium oxide (Ga₂O₃) and gallium hydroxide (Ga(OH)₃), and gallium oxide (Ga₂O₃) is particularly preferable. Examples of applicable compounds containing In include indium oxide (In₂O₃) and indium sulfate (In₂(SO₄)₃), and indium oxide (In₂O₃) is particularly preferable.

The aforementioned mixing of the raw material compounds may be either dry mixing or wet mixing. A preferred method is one capable of mixing the raw material compounds more evenly and, in this case, examples of applicable mixing devices include devices such as ball mill, V-type mixer, vibrating mill, Attritor, DYNO-MILL, and dynamic mill. Besides the mixing, it is also possible to obtain the mixture by coprecipitation, the hydrothermal technique, the dry up process to evaporate an aqueous solution to dryness, the sol-gel process, and so on.

The mixed oxide in the present invention can be obtained by calcining the foregoing mixture. As for calcining conditions, a calcining atmosphere is, for example, an inert gas atmosphere such as nitrogen, and the calcining temperature is a temperature of not less than 1000° C. and not more than 1300° C. The calcined product may be pulverized, if necessary, to obtain a pulverized product. The pulverization can be performed using a pulverizer which is normally industrially used, e.g., the ball mill, vibrating mill, Attritor, DYNO-MILL, and dynamic mill.

The mixed oxide can be obtained in the stereoscopic shape by sintering the calcined product or the pulverized product. By carrying out the sintering after calcination, it is feasible to improve uniformity of composition of the mixed oxide in the sintered body, to improve uniformity of crystal structure of the mixed oxide in the sintered body, and to suppress deformation of the thermoelectric conversion material. The sintered body comprising the mixed oxide can also be obtained by sintering the aforementioned mixture, instead of the sintering of the calcined product or the pulverized product.

As for sintering conditions, a sintering atmosphere is, for example, an inert gas atmosphere such as nitrogen, and sintering temperature is, for example, a temperature of not less than 1000° C. and not more than 1500° C. When the sintering temperature is less than 1000° C., it is difficult to cause sintering and the value of electrical conductivity (σ) of the resultant sintered body may decrease in some cases. When the sintering temperature is more than 1500° C., zinc may evaporate in some cases. A duration of retention at the sintering temperature is, for example, 5-15 hours. The temperature of the sintering is preferably from 1250° C. to 1450° C. When the aforementioned mixture contains the respective compounds each containing Zn, Ga, or In but not containing the compound containing Al, it is preferably sintered in the range of not less than 1350° C. and not more than 1450° C. When the aforementioned mixture contains the respective compounds each containing Zn, Ga, In or Al, it is preferably sintered in the range of not less than 1250° C. and not more than 1350° C.

It is preferable to mold the mixture, the calcined product, or the pulverized product, before the sintering. The molding and the sintering may be carried out simultaneously. The molding may be carried out in such a manner that the resultant molded body of them is formed in appropriate shape in the thermoelectric conversion module such as the prismatic shape like a rectangular parallelepiped, the platelike shape, or the cylindrical shape, and examples of applicable molding devices include the uniaxial press, cold isostatic press (CIP), mechanical press, hot press, and hot isostatic press (HIP). A binder, a dispersant, a mold release agent, etc. may be added to the mixture, the calcined product, or the pulverized product.

As another applicable method, the foregoing sintered body is pulverized and the resultant pulverized product is again sintered as described above.

Each of the above-described calcined product, pulverized product, and sintered body can be used as a thermoelectric conversion material as it is or after it is subjected to a surface treatment such as surface polishing or film coating.

<Film>

In the thermoelectric conversion material of the present invention, at least a part of the surface of the mixed oxide may be coated with a film. When the surface of the mixed oxide is coated with a film, the film can prevent evaporation of Zn in the thermoelectric conversion material in a high-temperature atmosphere. Furthermore, it can prevent degradation of characteristics of the thermoelectric conversion material, for example, even if the used atmosphere of the thermoelectric conversion material is an atmosphere easy to oxidize the mixed oxide, e.g., an oxidizing gas such as air. The film is preferably one containing at least one of silica, alumina, and silicon carbide as a major ingredient.

The thickness of the film is preferably in the range of 0.01 μm to 1 mm, more preferably in the range of 0.1 μm to 300 μm, and still more preferably in the range of 1 μm to 100 μm. If the thickness of the film is too small, it is hard to achieve the aforementioned effect of the film; if the thickness of the film is too large, the film becomes easier to crack.

When the sintered body having the stereoscopic shape is used for the thermoelectric conversion material of the present invention, the density of the mixed oxide, as relative density, is preferably not less than 80% in terms of obtaining a large value of electrical conductivity. The thermoelectric conversion materials of the present invention can have large values of electrical conductivity even if the relative density of the mixed oxide is approximately from 80% to 95%. The density of the mixed oxide can be controlled by particle size of the mixture, the calcined product, or the pulverized product, molding pressure in manufacture of the molded body, temperature of sintering, time of sintering, and so on.

The relative density can be determined by the formula below, where β (g/cm³) is the theoretical density of the mixed oxide and γ (g/cm³) measured density. The measured density can be obtained by the Archimedes method.

Relative density (%)=γ/β×100

<Thermoelectric Conversion Module>

The thermoelectric conversion module will be described below. The thermoelectric conversion module of the present invention comprises a plurality of n-type thermoelectric conversion materials; a plurality of p-type thermoelectric conversion materials; and a plurality of electrodes electrically serially connecting the plurality of p-type thermoelectric conversion materials with the plurality of n-type thermoelectric conversion materials in an alternate arrangement, and at least one material of the plurality of n-type thermoelectric conversion materials is the aforementioned thermoelectric conversion material of the present invention.

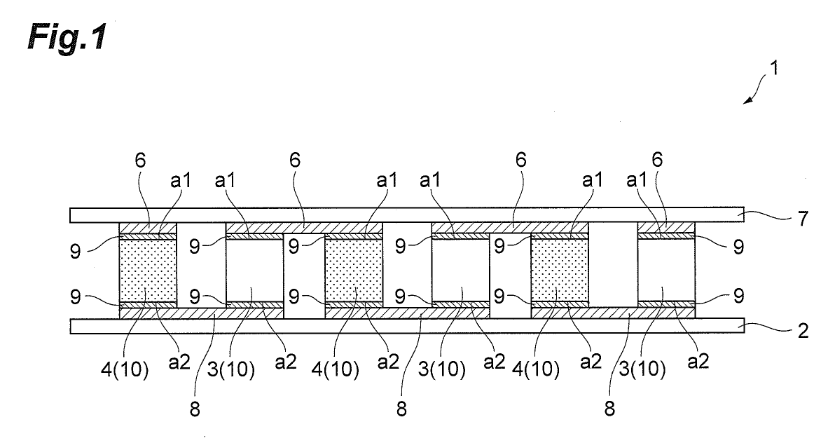

The below will describe an embodiment of the thermoelectric conversion module using the thermoelectric conversion materials. FIG. 1 is a cross-sectional view of thermoelectric conversion module 1 using thermoelectric conversion materials 10. As shown in FIG. 1, the thermoelectric conversion module 1 is provided with a first substrate 2, first electrodes 8, thermoelectric conversion materials 10, second electrodes 6, and a second substrate 7.

The first substrate 2 has, for example, a rectangular shape, has electrical insulation and thermal conductivity, and covers one end faces of the thermoelectric conversion materials 10. A material of this first substrate is, for example, alumina, aluminum nitride, magnesia, or the like.

The first electrodes 8 are provided on the first substrate 2 and electrically connect one end faces of mutually adjacent thermoelectric conversion materials 10 to each other. The first electrodes 8 can be formed at prescribed positions on the first substrate 2, for example, by a method such as the thin-film technology, e.g., sputtering or vacuum evaporation, or a method such as screen printing, plating, or thermal spraying. The electrodes 8 may be formed by joining metal plates or the like of prescribed shape onto the first substrate 2, for example, by a method such as soldering or brazing. There are no particular restrictions on a material of the first electrodes 8 as long as it is an electrically conductive material. In terms of improving the heat resistance, corrosion resistance, and adhesion of the electrodes to the thermoelectric conversion materials, the material of the electrodes is preferably a metal containing at least one element selected from the group consisting of titanium, vanadium, chromium, manganese, iron, cobalt, nickel, copper, molybdenum, silver, palladium, gold, tungsten, and aluminum, as a major ingredient. The major ingredient herein means an ingredient that is contained 50% by volume or more in the electrode material.

The second substrate 7 has, for example, a rectangular shape and covers the other end faces of the thermoelectric conversion materials 10. The second substrate 7 opposes to and in parallel with the first substrate 2. There are no particular restrictions on a material of the second substrate 7 as long as it is an electrically insulating and thermally conductive material, as the first substrate 2 is. The material can be, for example, alumina, aluminum nitride, magnesia, or the like.

The second electrodes 6 electrically connect the other end faces of mutually adjacent thermoelectric conversion materials 10 to each other. The second electrodes 6 can be formed at prescribed positions on the lower surface of the second substrate 7, for example, by a method such as the thin-film technology, e.g., sputtering or vacuum evaporation, or a method such as screen printing, plating, or thermal spraying. The thermoelectric conversion materials 10 are electrically connected in series by the first electrodes 8 and the second electrodes 6.

The p-type thermoelectric conversion materials 3 and the n-type thermoelectric conversion materials 4 are arranged in an alternate arrangement between the first substrate 2 and the second substrate 7. The each of both end faces of these thermoelectric conversion materials are fixed to the corresponding surfaces of the first electrodes 8 and the second electrodes 6 by joining using joint materials 9 such as an AuSb or PbSb type solder or a silver paste, and all the p-type thermoelectric conversion materials 3 and n-type thermoelectric conversion materials 4 are electrically connected in series in the alternate arrangement. The joint materials are preferably materials that are solid during use of the thermoelectric conversion module.

As described above, the both end faces a1, a2 of the plurality of p-type thermoelectric conversion materials 3 and n-type thermoelectric conversion materials 4 forming the thermoelectric conversion module 1 are opposed to the respective electrodes 6, 8 and are joined to the electrodes 6, 8, for example, through the respective joint materials 9.

The thermoelectric conversion material of the present invention is suitably used as the n-type thermoelectric conversion materials 4 in the thermoelectric conversion module. Examples of a material of the p-type thermoelectric conversion materials 3 include a mixed oxide such as NaCo₂O₄ or Ca₃Co₄O₉, a silicide such as MnSi_{1.73}, Fe₁₋ₓMnₓSi₂, Si_{0.8}Ge_{0.2}, or β-FeSi₂, a skutterudite such as CoSb₃, FeSb₃, or RFe₃CoSb₁₂ (where R represents La, Ce or Yb), or an alloy containing Te such as BiTeSb, PbTeSb, Bi₂Te₃, or PbTe. Among these, the p-type thermoelectric conversion materials 3 preferably contain the foregoing mixed oxide.

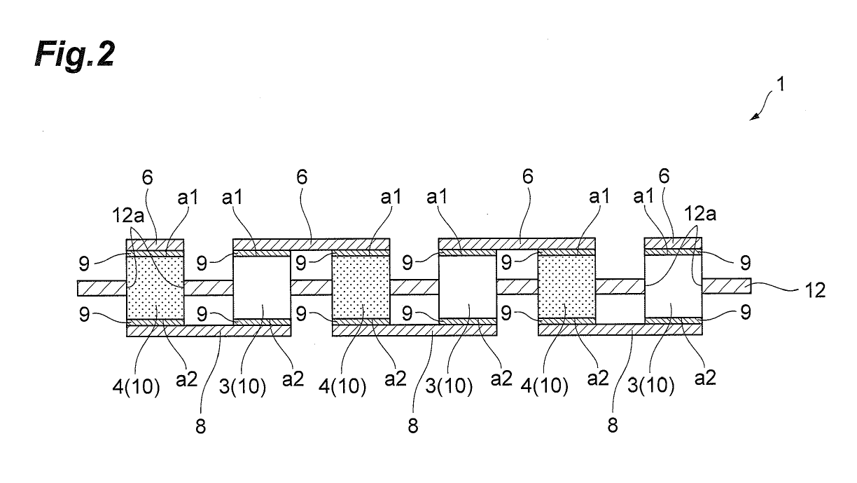

The thermoelectric conversion module does not have to be limited to the above embodiment. FIG. 2 shows a cross-sectional view of an example of skeleton type thermoelectric conversion module 1 using the thermoelectric conversion materials 10. FIG. 2 is different from FIG. 1 in that the thermoelectric conversion module 1 does not have the pair of substrates 2, 7 opposed to each other but is provided with a support frame 12, instead of them. The support frame 12 is interposed between the plurality of thermoelectric conversion materials 10 and located so as to surround central portions in the height direction of the respective thermoelectric conversion materials 10, and secures each of the thermoelectric conversion materials at an appropriate position. The other configuration is the same as that of the thermoelectric conversion module shown in FIG. 1.

The support frame 12 has thermal insulation and electrical insulation and, through holes 12a corresponding to the positions where the respective thermoelectric conversion materials 10 are to be located are formed in this support frame 12. The through holes 12a have a shape corresponding to the cross-sectional shape of the thermoelectric conversion materials 3, 4, e.g., a shape such as square or rectangular shape.

The thermoelectric conversion materials 10 are fitted in the respective through holes 12a. Since the space between internal wall faces of each through hole 12a and the side faces of each thermoelectric conversion material 10 is very narrow, the support frame 12 can fix the plurality of thermoelectric conversion materials 10. The internal wall faces of the through holes 12a may be filled with an adhesive or the like, if necessary, so as to fix the thermoelectric conversion materials 10 more firmly. In this manner, the thermoelectric conversion materials 10 are fixed by the support frame 12.

There are no particular restrictions on a material of the support frame 12 as long as it has thermal insulation and electrical insulation. The material of the support frame 12 can be, for example, a resin material or a ceramic material. The material of the support frame 12 may be suitably selected from materials that do not melt at an operating temperature of the thermoelectric conversion module 1. For example, when the operating temperature is around room temperature, the material may be polypropylene, ABS, polycarbonate, or the like; when the operating temperature is from room temperature to about 200° C., the material may be a super engineering plastic such as polyamide, polyimide, polyamide-imide, or polyether ketone; when the operating temperature is not less than about 200° C., the material may be a ceramic material such as alumina, zirconia, or cordierite. These materials may be used singly or in combination of two or more.

In the above-described skeleton type thermoelectric conversion module, different from the thermoelectric conversion module shown in FIG. 1, the plurality of thermoelectric conversion materials 10 and the plurality of electrodes 6, 8 are not sandwiched in between the substrates 2, 7. Therefore, the skeleton type thermoelectric conversion module can reduce thermal stress acting on each thermoelectric conversion material 10 and can reduce contact thermal resistance.

The present invention will be described below in further detail using examples.

### EXAMPLE 1 (Zn:Ga:In=0.98:0.01:0.19, sintering temperature: 1200° C.)

A ZnO powder (Kojundo Chemical Laboratory Co., Ltd.), a Ga₂O₃ powder (Kojundo Chemical Laboratory Co., Ltd.), and an In₂O₃ powder (Kojundo Chemical Laboratory Co., Ltd.) were weighed so that the molar ratio of Zn:Ga:In became 0.98:0.01:0.19. These were put together with ethanol and ZrO₂ balls into a resin pot, and they were mixed by a ball mill for twenty hours, and dried to obtain a mixture. This mixture was molded in a rectangular parallelepiped shape by uniaxial press using a die, and was further pressed under the pressure of 1800 kgf/cm² for one minute by isostatic press using a press machine (CIP of KOBELCO) to obtain a molded body. The resultant molded body was sintered by holding it at 1200° C. in a nitrogen atmosphere for ten hours to obtain sintered body 1.

Values of Seebeck coefficient (α) and electrical conductivity (σ) of the sintered body 1 were measured with a thermoelectric characteristic evaluator (ZEM-3, ULVAC-RIKO, Inc.). At 760° C. the sintered body 1 demonstrated the value of Seebeck coefficient (α) of 115 μV/K, the value of electrical conductivity (σ) of 1.3×10⁴ (S/m), and the value of power factor (α²×σ) of 1.8×10⁻⁴ W/mK⁻². The relative density of the sintered body 1 was 86.2%. The value of thermal conductivity (κ) was obtained by substituting values of thermal diffusivity (γ) and specific heat (Cp) determined by the laser flash method, and the foregoing relative density into the following formula.

κ=γ×Cp×ρ(where ρ is the relative density of the sintered body)

The value of thermal conductivity (κ) obtained was 0.9 W/mK. The value of performance index (Z) obtained using these values of α, σ, and κ was 2.0×10⁻⁴ K⁻¹, which was extremely large.

### EXAMPLE 2 (Zn:Ga:In=0.98:0.01:0.19, sintering temperature: 1300° C.)

Sintered body 2 was obtained in the same manner as in Example 1 except for the sintering temperature of 1300° C. Values of Seebeck coefficient (α) and electrical conductivity (σ) of the sintered body 2 were measured in the same manner as in Example 1. The value of Seebeck coefficient (α) was 130 μV/K, the value of electrical conductivity (σ) 9.6×10³ (S/m), and the value of power factor (α²×σ) 1.6×10⁻⁴ W/mK⁻². The relative density of the sintered body 2 was 86.6%. The value of thermal conductivity (κ) of the sintered body 2 was determined in the same manner as in Example 1. The value of thermal conductivity (κ) determined was 0.8 W/mK. The value of performance index (Z) obtained using these values of α, σ, and κ was 2.0×10⁻⁴ K⁻¹, which was extremely large.

### EXAMPLE 3 (Zn:Ga:In=0.98:0.01:0.19, sintering temperature: 1400° C.)

Sintered body 3 was obtained in the same manner as in Example 1 except for the sintering temperature of 1400° C. Values of Seebeck coefficient (α) and electrical conductivity (σ) of the sintered body 3 were measured in the same manner as in Example 1. The value of Seebeck coefficient (α) was 120 μV/K, the value of electrical conductivity (σ) 1.8×10⁴ (S/m), and the value of power factor (α²×σ) 2.6×10⁻⁴ W/mK⁻². The relative density of the sintered body 3 was 82.4%. The value of thermal conductivity (κ) of the sintered body 3 was determined in the same manner as in Example 1. The value of thermal conductivity (κ) determined was 0.8 W/mK. The value of performance index (Z) obtained using these values of α, σ, and κ was 3.1×10⁻⁴ K⁻¹, which was extremely large.

### EXAMPLE 4 (Zn:Al:Ga:In=0.900:0.002:0.002:0.096, sintering temperature: 1200° C.)

A ZnO powder (Kojundo Chemical Laboratory Co., Ltd.), an Al₂O₃ powder (Kojundo Chemical Laboratory Co., Ltd.), a Ga₂O₃ powder (Kojundo Chemical Laboratory Co., Ltd.), and an In₂O₃ powder (Kojundo Chemical Laboratory Co., Ltd.) were weighed so that the molar ratio of Zn:Al:Ga:In became 0.900:0.002:0.002:0.096. These were put together with ethanol and ZrO₂ balls into a resin pot, and they were mixed by a ball mill for twenty hours, and dried to obtain a mixture. This mixture was molded in a rectangular parallelepiped shape by uniaxial press using a die, and was further pressed under the pressure of 1800 kgf/cm² for one minute by isostatic press using a press machine (CIP of KOBELCO) to obtain a molded body. The resultant molded body was sintered by holding it at 1200° C. in a nitrogen atmosphere for ten hours to obtain sintered body 4.

Values of Seebeck coefficient (α) and electrical conductivity (σ) of the sintered body 4 were measured in the same manner as in Example 1. The value of Seebeck coefficient (α) was 156 μV/K, the value of electrical conductivity (σ) 1.0×10⁴ (S/m), and the value of power factor (α²×σ) 2.4×10⁻⁴ W/mK⁻². The relative density of the sintered body 4 was 92.8%. The value of thermal conductivity (κ) of the sintered body 4 was determined in the same manner as in Example 1. The value of thermal conductivity (κ) determined was 2.0 W/mK. The value of performance index (Z) obtained using these values of α, σ, and κ was 1.2×10⁻⁴ K⁻¹, which was extremely large.

### EXAMPLE 5 (Zn:Al:Ga:In=0.900:0.002:0.002:0.096, sintering temperature: 1300° C.)

Sintered body 5 was obtained in the same manner as in Example 4 except for the sintering temperature of 1300° C. Values of Seebeck coefficient (α) and electrical conductivity (σ) of the sintered body 5 were measured in the same manner as in Example 1. The value of Seebeck coefficient (α) was 173 μV/K, the value of electrical conductivity (σ) 2.0×10⁴ (S/m), and the value of power factor (α²×σ) 5.9×10⁻⁴ W/mK⁻². The relative density of the sintered body 5 was 90.6%. The value of thermal conductivity (κ) of the sintered body 5 was determined in the same manner as in Example 1. The value of thermal conductivity (κ) determined was 2.0 W/mK. The value of performance index (Z) obtained using these values of α, σ, and κ was 2.9×10⁻⁴ K⁻¹, which was extremely large.

### EXAMPLE 6 (Zn:Al:Ga:In=0.900:0.002:0.002:0.096, sintering temperature: 1400° C.)

Sintered body 6 was obtained in the same manner as in Example 4 except for the sintering temperature of 1400° C. Values of Seebeck coefficient (α) and electrical conductivity (σ) of the sintered body 6 were measured in the same manner as in Example 1. The value of Seebeck coefficient (α) was 137 μV/K, the value of electrical conductivity (σ) 2.0×10⁴ (S/m), and the value of power factor (α²×σ) 3.7×10⁻⁴ W/mK⁻². The relative density of the sintered body 6 was 93.1%. The value of thermal conductivity (κ) of the sintered body 6 was determined in the same manner as in Example 1. The value of thermal conductivity (κ) determined was 1.8 W/mK. The value of performance index (Z) obtained using these values of α, σ, and κ was 2.0×10⁻⁴K⁻¹, which was extremely large.

### Comparative Example 1 (Zn:Al:Ga=0.996:0.002:0.002, sintering temperature: 1200° C.)

A ZnO powder (Kojundo Chemical Laboratory Co., Ltd.), an Al₂O₃ powder (Kojundo Chemical Laboratory Co., Ltd.), and a Ga₂O₃ powder (Kojundo Chemical Laboratory Co., Ltd.) were weighed so that the molar ratio of Zn:Al:Ga became 0.996:0.002:0.002. These were put together with ethanol and ZrO₂ balls into a resin pot, and they were mixed by a ball mill for twenty hours and dried to obtain a mixture. This mixture was molded in a rectangular parallelepiped shape by uniaxial press using a die and was pressed under the pressure of 1800 kgf/cm² for one minute by isostatic press using a press machine (CIP of KOBELCO) to obtain a molded body. The resultant molded body was sintered by holding it at 1200° C. in a nitrogen atmosphere for ten hours to obtain sintered body R1.

Values of Seebeck coefficient (α) and electrical conductivity (σ) of the sintered body R1 were measured in the same manner as in Example 1. The value of Seebeck coefficient (α) was 113 μV/K, the value of electrical conductivity (σ) 6.2×10⁴ (S/m), and the value of power factor (α²×σ) 7.8×10⁻⁴ W/mK⁻². The relative density of the sintered body R1 was 98.0%. The value of thermal conductivity (κ) of the sintered body R1 was determined in the same manner as in Example 1. The value of thermal conductivity (κ) determined was 45.5 W/mK. The value of performance index (Z) obtained using these values of α, σ, and κ was 1.7×10⁻⁵ K⁻¹, which was small.

### Comparative Example 2 (Zn:Al:Ga=0.96:0.01:0.01, sintering temperature: 1200° C.)

Sintered body R2 was obtained in the same manner as in Comparative Example 1 except for the molar ratio of Zn:Al:Ga of 0.96:0.01:0.01. Values of Seebeck coefficient (α) and electrical conductivity (σ) of the sintered body R2 were measured in the same manner as in Example 1. The value of Seebeck coefficient (α) was 100 μV/K, the value of electrical conductivity (σ) 8.1×10⁴ (S/m), and the value of power factor (α²×σ) 8.0×10⁻⁴ W/mK⁻². The relative density of the sintered body R2 was 98.2%. The value of thermal conductivity (κ) of the sintered body R2 was determined in the same manner as in Example 1. The value of thermal conductivity (κ) determined was 36.5 W/mK. The value of performance index (Z) obtained using these values of α, σ, and κ was 2.2×10⁻⁵ K⁻¹, which was small.

### LIST OF REFERENCE SIGNS

1 thermoelectric conversion module, 2 first substrate, 3 p-type thermoelectric conversion materials, 4 n-type thermoelectric conversion materials, 6 second electrodes, 7 second substrate, 8 first electrodes, 9 joint materials, 10 thermoelectric conversion materials, 12 support frame, 12a through holes, and, a1 and a2 end faces of thermoelectric conversion materials opposed to electrodes.

1. A thermoelectric conversion material comprising a mixed oxide containing Zn, Ga, and In.

2. The thermoelectric conversion material according to claim 1, wherein the ratio of a molar amount of Ga to a total molar amount of Zn, Ga, and In is not less than 0.001 and not more than 0.1.

3. The thermoelectric conversion material according to claim 1, wherein the ratio of a molar amount of In to a total molar amount of Zn, Ga, and In is not less than 0.001 and not more than 0.3.

4. The thermoelectric conversion material according to claim 1, wherein the relative density of the mixed oxide is not less than 80%.

5. The thermoelectric conversion material according to claim 1, wherein the mixed oxide further contains Al.

6. The thermoelectric conversion material according to claim 5, wherein the ratio of a molar amount of Al to a total molar amount of Zn, Ga, Al, and In is not less than 0.001 and not more than 0.1.

7. The thermoelectric conversion material according to claim 5, wherein the ratio of a molar amount of Ga to a total molar amount of Zn, Ga, Al, and In is not less than 0.001 and not more than 0.1.

8. The thermoelectric conversion material according to claim 5, wherein the ratio of a molar amount of In to a total molar amount of Zn, Ga, Al, and In is not less than 0.001 and not more than 0.3.

9. The thermoelectric conversion material according to claim 5, wherein the relative density of the mixed oxide is not less than 80%.

10. The thermoelectric conversion material according to claim 1, wherein at least a part of a surface of the mixed oxide is coated with a film.

11. A thermoelectric conversion module comprising:
a plurality of n-type thermoelectric conversion materials;
a plurality of p-type thermoelectric conversion materials; and
a plurality of electrodes electrically serially connecting the plurality of p-type thermoelectric conversion materials with the plurality of n-type thermoelectric conversion materials in an alternate arrangement,
wherein at least one material of the plurality of n-type thermoelectric conversion materials is the thermoelectric conversion material as set forth in claim 1.
